(19) United States
(12) Patent Application Publication
(10) Pub. No.: US 2007/0200253 A1
(43) Pub. Date: Aug. 30, 2007

(54) Electronic assembly and method for forming the same

(76) Inventors: Bishnu P. Gogoi, Scottsdale, AZ (US); Vijay Sarihan, Paradise Valley, AZ (US)

Correspondence Address: INGRASSIA FISHER & LORENZ, P.C. (FS), 7150 E. CAMELBACK ROAD, SUITE 325, SCOTTSDALE, AZ, 85251, US

(21) Appl. No.: 11/363,622

(22) Filed: Feb. 28, 2006

(51) Int. Cl. H01L 23/48

(52) U.S. Cl. 257/779

(57) ABSTRACT

Methods are provided for forming an electronic assembly (54). At least one depression (38) is formed in a surface of a substrate (20). A contact formation (44) is placed in the depression. A microelectronic die (46) is attached to the substrate using the contact formation. An electronic assembly is also provided. The invention further provides an electronic assembly. The electronic assembly includes a substrate having a plurality of depressions formed thereon, a microelectronic die having a microelectronic device formed therein, and a plurality of contact formations bonded to and interconnecting the substrate and the microelectronic die. Each of the contact formations are positioned within a respective depression on the substrate.

### TECHNICAL FIELD

The present invention generally relates to an electronic assembly and a method for forming an electronic assembly, and more particularly relates to a method for attaching a microelectronic die to a substrate.

### BACKGROUND

Integrated circuit devices are formed on semiconductor substrates, or wafers. The wafers are then sawed into microelectronic dies (or “dice”), or semiconductor chips, with each die carrying a respective integrated circuit. Each semiconductor chip is typically mounted to a package, or carrier, substrate or a lead frame using either wire bonding or “flip-chip” connections. The packaged chip is then mounted to a circuit board, or motherboard, before being installed in an electronic or computing system.

Polymers are often used to mount semiconductor chips to lead frames, and one common method involves what is known as Room-Temperature Vulcanization (RTV), where the particular polymer used will cure at room temperature without the need for additional heating. The configuration of the polymer used to interconnect the semiconductor chip and the lead frame can vary from an entire slab of polymer between the chip and lead frame to just a few, small dots of the polymer at selected locations.

In either case, the methods used for placing or forming the polymer on the lead frame are inherently inaccurate and imprecise. For example, syringes are often used to form the dots of the polymer on the lead frame. The movements of the syringes are difficult to control or predict. Therefore, the exact locations of the dots on the lead frame are not known. Additionally, the exact volumes of the dots dispensed from the syringes are not accurately known. Therefore, it is difficult to know the exact sizes of the dots.

Particular devices, such as strained silicon devices, silicon germanium devices, and microelectromechanical system (MEMS) devices, are particularly sensitive to mechanical stresses. The inconsistencies in the placement and formation of the polymers on the lead frames can add to the mechanical stresses experienced by such devices, which can affect the performance of the particular device. In some cases, the stresses can lead to mechanical failure of the connections between the device and the lead frame.

Accordingly, it is desirable to provide a method for attaching a microelectronic die to a substrate with contact formations that have precisely known locations and sizes. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawing figures, wherein like numerals denote like elements, and

FIG. 1 is an isometric view of a lead frame substrate including a plurality of lead frames;

FIG. 2 is a cross-sectional side view of one of the lead frames illustrated in FIG. 1 taken along line 2-2;

FIG. 3 is an isometric view of the lead frame substrate illustrated in FIG. 1 with a plurality of depressions formed thereon;

FIG. 4 is a cross-sectional side view of one of the lead frames illustrated in FIG. 3 taken along line 4-4;

FIG. 5 is a top plan view of the lead frame illustrated in FIG. 4;

FIG. 6 is a cross-section side of the lead frame of FIG. 4 illustrating a plurality of contact formations being placed thereon;

FIG. 7 is a top plan view of the of the lead frame illustrated in FIG. 6;

FIG. 8 is a cross-sectional side view of the lead frame of FIG. 6 after the contact formations have been placed thereon;

FIG. 9 is a top plan view of the lead frame illustrated in FIG. 8;

FIG. 10 is a cross-section side view of the lead frame illustrated in FIG. 8 illustrating a microelectronic die being placed on the contact formations;

FIG. 11 is a cross-sectional side view of an electronic assembly including the lead frame of FIG. 10 after being separated from the lead frame substrate and with a plurality of wire bonds formed thereon; and

FIG. 12 is a top plan view of the electronic assembly of FIG. 11.

### DETAILED DESCRIPTION

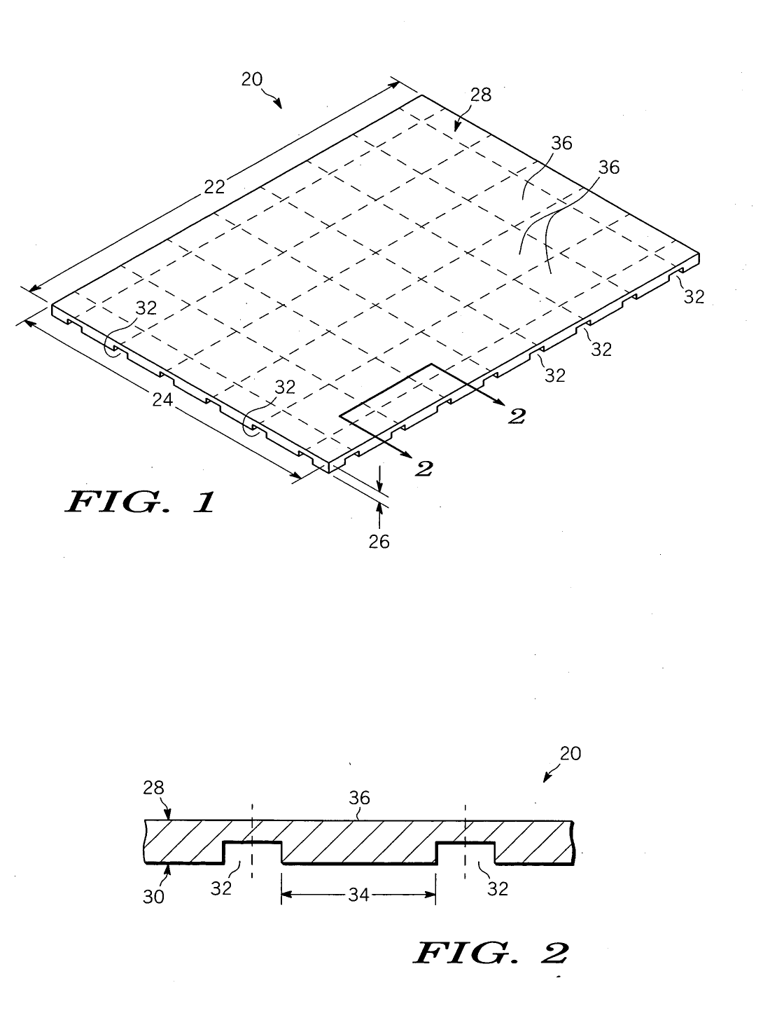

The following detailed description is merely exemplary in nature and is not intended to limit the invention or the application and uses of the invention. Furthermore, there is no intention to be bound by any expressed or implied theory presented in the preceding technical field, background, brief summary or the following detailed description. It should also be noted that FIGS. 1-12 are merely illustrative and may not be drawn to scale.

FIG. 1 to FIG. 12 illustrate a method for forming an electronic assembly. A plurality of depressions, with precisely known locations, are formed on a lead frame substrate. A plurality of contact formations, with precisely known sizes and shapes, are then placed, or formed, on the substrate so that one contact formation occupies each of the depressions. A microelectronic die, with a microelectronic device formed therein, is then placed on the contact formations. The contact formations are then heated to bond the contact formations to the substrate and the microelectronic die. The lead frame substrate is then divided into individual lead frames.

FIGS. 1 and 2 illustrate a lead frame substrate 20. The lead frame substrate is substantially rectangular with, for example, a length 22 of approximately 200 mm, a width 24 of approximately 100 mm, and a thickness 26 of approximately 3 mm and has an upper surface 28 and a lower surface 30. As illustrated, the lower surface 30 includes a series of separation trenches 32 formed therein. Although not specifically illustrated, the lead frame substrate 20 has a reduced thickness at the trenches 32 of, for example, approximately 1.5 mm. The trenches 32 are separated by a distance 34 of, for example, between 3 and 10 mm. The lead frame substrate is made of an electrically conductive material. In one embodiment, the lead frame substrate is made of a metal, such as, for example, copper or aluminum.

A first set of the trenches 32 extends in a direction that is substantially parallel to the length 22 of the substrate 20, and a second set of the trenches 32 extend in a direction that is substantially parallel to the width 24 of the substrate. Thus, the first and second sets of trenches intersect to form a grid, as indicated by the dashed lines shown on the upper surface 28 of the substrate 20. As will be discussed in greater detail below, the grid may divide the substrate 20 into a plurality of lead frames 36. It should also be noted that although that some of the following processes may be shown as being performed on only one portion, or lead frame 36, of the lead frame substrate 20, each of the steps may be performed on substantially the entire lead frame substrate 20, or multiple lead frames 36, simultaneously.

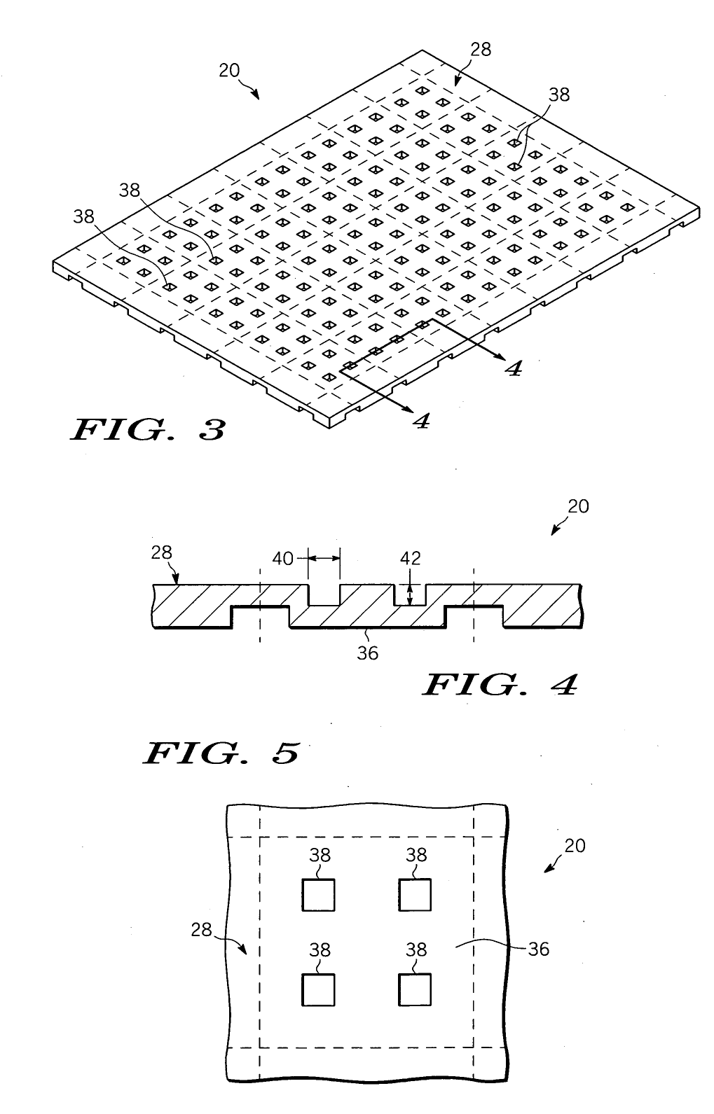

As illustrated in FIGS. 3, 4, and 5, a plurality of depressions or dimples 38 are then formed in (or “on”) the upper surface 28 of the lead frame substrate 20. In one embodiment, the depressions 38 are positioned such that each lead frame 36 includes four depressions 38 at a central portion thereof arranged in a square, as shown in FIG. 5. Referring to FIG. 5 in combination with FIG. 4, the depressions 38 are square and have, for example, a width 40 of between 50 and 150 microns and a depth 42 of between 10 and 30 microns. All of the depressions 38 may have substantially identical dimensions.

In one embodiment, the depressions 38 are formed using etching, as is commonly understood in the art. The depressions 38 may also be formed using other known techniques, such as punching, drilling, or stamping. As mentioned above, the formation of the depressions 38 may take place over the entire lead frame substrate 20 so that the size, shape, and placement of the depressions 38, as well as the spacing and orientation of the depressions 38 relative to one another, may be determined with a high level of precision. It should be noted that different numbers, sizes, and shapes of the depressions 38 may be used, as is commonly understood.

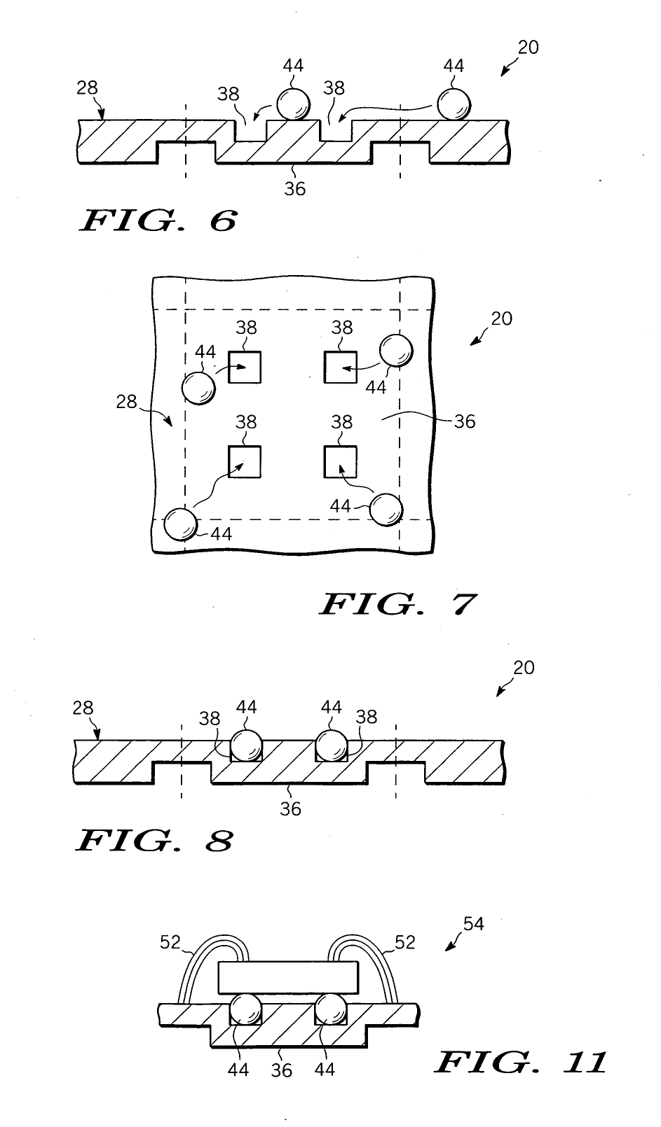

Referring to FIGS. 6-9, a plurality of contact formations 44 are then placed on the upper surface 28 of the lead frame substrate 20. As shown in FIGS. 6 and 7, in one embodiment, the contact formations 44 are solder balls and are placed on the substrate 20 using a method known as “rolling.” As will be appreciated by one skilled in the art, an excessive number of the contact formations 44 are essentially “poured” on the lead frame substrate 20 and allowed to roll across the upper surface 28 thereof.

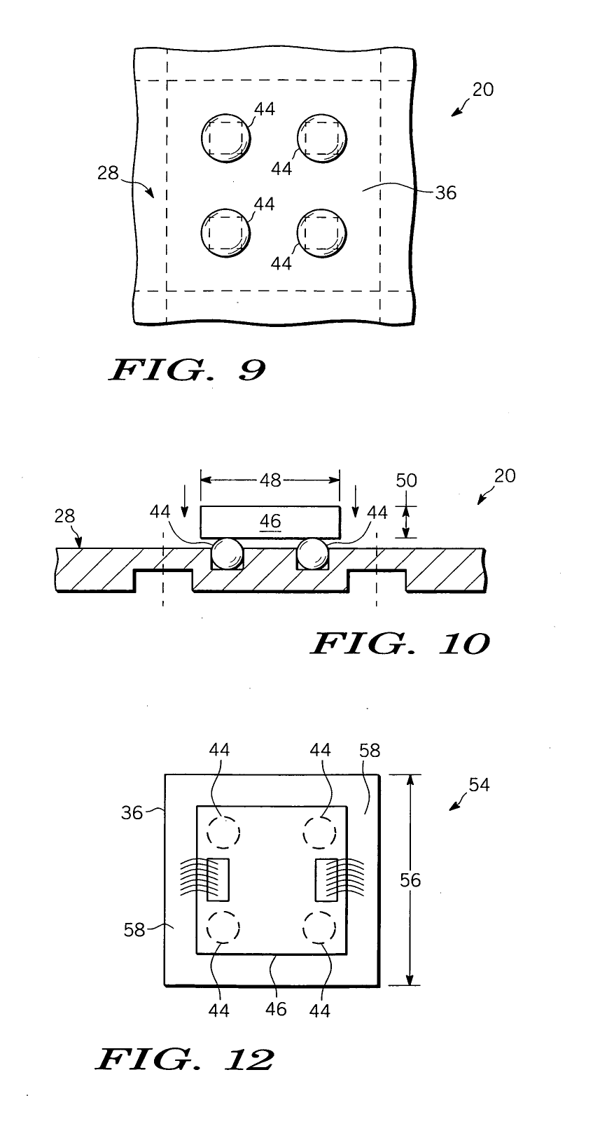

As the contact formations 44 roll across the upper surface 28, many of the contact formations 44 fall into one of the depressions 38 and become “stuck” so long as the lead frame substrate 20 remains in a substantially horizontal orientation, as shown in FIGS. 8 and 9. The lead frame substrate 20 may also be shaken to assist in removing the contact formations 44 that have not become placed in a depression. The unused contact formations may roll off the edges of the substrate 20 and may be recycled or reused.

In the illustrated embodiment, the contact formations 44, or solder balls, are substantially spherical with diameters of, for example, between 100 and 160 microns. The solder balls are all substantially identical and made of, for example, a lead-free solder, such as tin copper (SnCu) or a lead-containing copper, such as lead tin (PbSn). Other processes besides rolling may be used to place, or form, the contact formations 44 within the depressions 38, such as stenciling, evaporation, and placement using a pick-and-place machine, as is commonly understood in the art. Additionally, other materials besides solders, such as polymers, may be used to form the contact formations 44 and the sizes and shapes of the contact formations 44 may vary, as will be appreciated by one skilled in the art. It should be noted that the use or formation of the solder balls provides contact formations with very consistent and precise sizes, shapes, and volumes.

As shown in FIG. 10, a microelectronic die 46 is then placed on the contact formations 44. The microelectronic die 46 may be substantially square with, for example, a side length 48 of between 3 and 8 mm and a thickness 50 of between 300 and 1000 microns. Although not specifically illustrated, the microelectronic die 46 may include a microelectronic device formed therein. The microelectronic device may be, for example, an integrated circuit, such as a strained silicon complimentary metal-oxide-semiconductor (CMOS) device or a silicon germanium device, a microelectromechanical system (MEMS) device, such as gyroscope, accelerometer, resonator, filter, or oscillator, or any type of stress-sensitive device, as is commonly understood.

Looking ahead to FIG. 12, the microelectronic die 46 is placed on the contact formations 44, and the contact formations 44 are spaced apart, such that each of the contact formations 44 is located under the microelectronic die 46 at a respective comer thereof. However, as will be appreciated by one skilled in the art, the arrangement and spacing of the depressions 38 may be varied to that the contact formations 44 lie under different portions of the microelectronic die 46 and to accommodate different sizes of dice.

Referring again to FIG. 10, as is commonly understood, a force may be applied on the microelectronic die 46 towards the lead frame substrate 20 is temporarily secure the die 46 to the contact formations 44 and thus the lead frame substrate 20. The assembly shown in FIG. 10 also may then also undergo a heating process to bring the contact formations 44 to “reflow.” The heating process may take place in an apparatus known in the art as an “oven,” and may raise the temperature of the contact formations 44 to a temperature of, for example, between 220° and 400° C. During the reflow process, the contact formations 44 bond to the lead frame substrate 20 and the microelectronic die 46 thus securely attaching the microelectronic die 46 to the lead frame substrate 20. Although not shown, solder flux may be used to assist with the attachment of the solder balls, as in commonly understood.

It should be noted that in the embodiment illustrated in FIG. 12, the contact formations 44 may be used solely to attach or mount the microelectronic die 46 to the lead frame substrate 20. That is, the contact formations 44 may not provide an electrical connection for the microelectronic die 46. More specifically, the contact formations 44 may not be electrically connected to the microelectronic device within the microelectronic die or the lead frame substrate 20.

Referring to FIGS. 11 and 12, a plurality of wire bonds 52 are then formed between opposing outer portions of an upper surface of the microelectronic die 46 and corresponding portions of the respective lead frame 36. As is commonly understood, the wire bonds 52 may be formed using a loop wire bonding process and may electrically connect the microelectronic device within the microelectronic die 46 to the lead frame 36. Additionally, the lead frame substrate 20 may be separated (or singulated) into the individual lead frames 36, as shown in FIGS. 1 and 3, to form a plurality of electronic assemblies 54, or microelectronic packages, each including one of the lead frames 36, four of the contact formations 44, one of the microelectronic dies 46, and several of the wire bonds 52, as shown in FIGS. 11 and 12.

Once separated from the lead substrate frame 20, each of the lead frames 36 is substantially square with a side length 56 of, for example, approximately 10 mm. Additionally, the lead frames 36 may include leads 58 formed from the outer portions thereof, which are electrically connected to the microelectronic device within the microelectronic die 46 through the wire bonds 52.

After final processing steps, which may include encapsulating the microelectronic die 46 and the wire bonds 52, the electronic assemblies 54 are installed in various electronic or computing systems. Electrical connections are made to the assemblies 54 via the leads 58, through which various power and input/output (I/O) are sent.

One advantage of the method and assembly described above is that because of the depressions formed in the lead frame substrate and the use of contact formations, the locations and sizes of the contact formations are precisely known. Therefore, the stresses that are experienced by the microelectronic die, and the microelectronic device therein, can be accurately predicted. Thus, the design of the microelectronic die can be improved to compensate for the stresses, which leads improved device performance and reliability.

The invention provides a method for forming an electronic assembly. At least one depression is formed in a surface of a substrate. A contact formation is placed in the depression. A microelectronic die is attached to the substrate using the contact formation.

Attaching the microelectronic die to the substrate may include heating the contact formation to cause the contact formation to reflow and bond to the substrate and the microelectronic die. The substrate may include an electrically conductive material. The electrically conductive material may be a metal. The contact formation may include a metal. The contact formation may be a solder ball. The microelectronic die may include a microelectronic device formed therein.

The method may also include forming wire bonds between the microelectronic die and the substrate. The wire bonds may electrically connect the microelectronic device within the microelectronic die to the substrate. The solder ball may not be electrically connected to the microelectronic device within the microelectronic die after the microelectronic die is attached to the substrate. The microelectronic device may include at least one of a strained silicon device, a silicon germanium device, a microelectromechanical system (MEMS) device, and a stress-sensitive device.

The invention also provides a method for forming an electronic assembly. A plurality of depressions are formed in a surface of a substrate. Each of a plurality of solder balls are placed within a respective one of the depressions. A microelectronic die is positioned such that the microelectronic die is in contact with at least two of the solder balls. The solder balls are heated to reflow to cause the solder balls to attach the microelectronic die to the substrate.

Each depression may have a depth of greater than 10 microns. The substrate may include a metal. The microelectronic die may include a microelectronic device formed therein. The microelectronic device may include at least one of a strained silicon device, a silicon germanium device, a microelectromechanical system (MEMS) device, and a stress-sensitive device.

The method may also include forming wire bonds between the microelectronic die and the substrate. The wire bonds may electrically connect the microelectronic device within the microelectronic die to the substrate. The solder balls may not be electrically connected to the microelectronic device within the microelectronic die.

The invention further provides an electronic assembly. The electronic assembly includes a substrate having a plurality of depressions formed thereon, a microelectronic die having a microelectronic device formed therein, and a plurality of contact formations bonded to and interconnecting the substrate and the microelectronic die. Each of the contact formations are positioned within a respective depression on the substrate.

The substrate may include a metal and the contact formations may be solder balls. The solder balls may not be electrically connected to the microelectronic device within the microelectronic die.

The electronic assembly may also include a plurality of wire bonds interconnecting the microelectronic die and the substrate. The wire bonds may be electrically connected to the microelectronic device. The microelectronic device may include at least one of a strained silicon device, a silicon germanium device, a microelectromechanical system (MEMS) device, and a stress-sensitive device.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

1. A method for forming an electronic assembly comprising:
forming at least one depression in a surface of a substrate;
placing a contact formation in the depression; and
attaching a microelectronic die to the substrate using the contact formation.

2. The method of claim 1, wherein the attaching comprises heating the contact formation, said heating causing the contact formation to reflow and bond to the substrate and the microelectronic die.

3. The method of claim 2, wherein the substrate comprises an electrically conductive material.

4. The method of claim 3, wherein the electrically conductive material is a metal.

5. The method of claim 4, wherein the contact formation comprises a metal.

6. The method of claim 5, wherein the contact formation is a solder ball.

7. The method of claim 6, wherein the microelectronic die comprises a microelectronic device formed therein.

8. The method of claim 7, further comprising forming wire bonds between the microelectronic die and the substrate, said wire bonds electrically connecting the microelectronic device within the microelectronic die to the substrate.

9. The method of claim 8, wherein the solder ball is not electrically connected to the microelectronic device within the microelectronic die after the microelectronic die is attached to the substrate.

10. The method of claim 9, wherein the microelectronic device is at least one of a strained silicon device, a silicon germanium device, a microelectromechanical system (MEMS) device, and a stress-sensitive device.

11. A method for forming an electronic assembly comprising:
forming a plurality of depressions in a surface of a substrate;
placing each of a plurality of solder balls within a respective one of the depressions;
positioning a microelectronic die such that the microelectronic die is in contact with at least two of the solder balls; and
heating the solder balls to reflow, said reflow causing the solder balls to attach the microelectronic die to the substrate.

12. The method of claim 11, wherein each depression has a depth of greater than 10 microns.

13. The method of claim 12, wherein the substrate comprises a metal.

14. The method of claim 13, wherein the microelectronic die comprises a microelectronic device formed therein, the microelectronic device comprising at least one of a strained silicon device, a silicon germanium device, a microelectromechanical system (MEMS) device, and a stress-sensitive device.

15. The method of claim 14, further comprising forming wire bonds between the microelectronic die and the substrate, said wire bonds electrically connecting the microelectronic device within the microelectronic die to the substrate, and wherein the solder balls are not electrically connected to the microelectronic device within the microelectronic die.

16. An electronic assembly comprising:
a substrate having a plurality of depressions formed thereon;
a microelectronic die having a microelectronic device formed therein; and
a plurality of contact formations bonded to and interconnecting the substrate and the microelectronic die, each of the contact formations being positioned within a respective depression on the substrate.

17. The electronic assembly of claim 16, wherein the substrate comprises a metal and the contact formations are solder balls.

18. The electronic assembly of claim 17, wherein the solder balls are not electrically connected to the microelectronic device within the microelectronic die.

19. The electronic assembly of claim 18, further comprising a plurality of wire bonds interconnecting the microelectronic die and the substrate, the wire bonds being electrically connected to the microelectronic device.

20. The electronic assembly of claim 19, wherein the microelectronic device comprises at least one of a strained silicon device, a silicon germanium device, a microelectromechanical system (MEMS) device, and a stress-sensitive device.
